(19) United States
(12) Patent Application Publication
(10) Pub. No.: US 2025/0035695 A1
(43) Pub. Date: Jan. 30, 2025

(54) METHOD AND DEVICE FOR DETECTING AND LOCATING INSULATION STATE OF CONVERSION SYSTEM

(71) Applicant: Delta Electronics (Shanghai) Co.,Ltd., Shanghai (CN)

(72) Inventors: Teng LIU, Shanghai (CN); Dehui ZHANG, Shanghai (CN); Jie ZHAO, Shanghai (CN); Weiqiang ZHANG, Shanghai (CN)

(21) Appl. No.: 18/766,668

(22) Filed: Jul. 9, 2024

(30) Foreign Application Priority Data
Jul. 27, 2023 (CN) 202310934674.8

(51) Int. Cl. G01R 31/12; G01R 31/62

(52) U.S. Cl. CPC G01R 31/1272; G01R 31/62

(57) ABSTRACT

The invention discloses a method and device for detecting and locating insulation state of a conversion system, the conversion system including: a converter module including n conversion units, where n≥2, each conversion unit including a transformer including a first winding and a second winding; and a connection element connected between the first winding and the second winding of the transformer; the method for detecting and locating insulation state including comparing a value reflecting a current flowing the connection element before change of the state of at least one switch with a value reflecting the current flowing the connection element after change of the state of the at least one switch, and determining which of the n conversion units has insulation abnormality based on comparison result.

### CROSS-REFERENCE TO RELATED APPLICATIONS

This non-provisional application claims priority under 35 U.S.C. § 119(a) on Patent Application 202310934674.8 filed in P.R. China on Jul. 27, 2023, the entire contents of which are hereby incorporated by reference.

Some references, if any, which may include patents, patent applications and various publications, may be cited and discussed in the description of this application. The citation and/or discussion of such references, if any, is provided merely to clarify the description of the present application and is not an admission that any such reference is “prior art” to the application described herein. All references listed, cited and/or discussed in this specification are incorporated herein by reference in their entireties and to the same extent as if each reference was individually incorporated by reference.

### BACKGROUND OF THE INVENTION

### 1. Field of the Invention

The invention relates to the field of power electronic technology, and in particular, to a method and device for detecting and locating insulation state of a conversion system.

### 2. Related Art

Power transformers in medium-high voltage and high-frequency isolation converters, which serve as an important component in electrical isolation between high and low voltage circuits, shall bear a working voltage for a long time in the system and an overvoltage stress in faulty conditions. With development of the converter system towards a direction of high frequency, high voltage and high power density, a volume of the isolation transformer is decreased, and the main insulation structure between primary and secondary sides of the transformer shall bear a higher electric field stress, and the higher the electric field stress is, the higher a risk of insulation failure will be. Meanwhile, aging of the electric field stress for a long time and insulation abnormality will increase the risk of insulation failure, thereby causing serious accidents, and loss of life and property.

Currently, the common medium-high voltage and high-frequency isolation converter systems are often formed of a plurality of modules cascaded, and the converter systems often include a plurality of high-frequency isolation transformers. When the converter systems have insulation abnormality, and maintenance is required, since the existing method cannot accurately locate which module in the system has insulation abnormality, the modules in the system often shall be checked respectively, so a large labor cost is required for disassembly and maintenance, while expensive high-voltage detection devices are also required for aided detection.

Therefore, it is urgent to provide a method and device for detecting and locating insulation state of a conversion system, which can locate position of modules that have insulation abnormality in the conversion system, simplifies fault maintenance work, and reduces maintenance cost.

### SUMMARY OF THE INVENTION

An object of the invention is to provide a method and device for detecting and locating insulation state of a conversion system, which can solve one or more deficiencies in the prior art.

In order to achieve the object, the invention provides a method for detecting and locating insulation state of a conversion system, the conversion system including: a converter module including n conversion units, where n≥2, each conversion unit including a transformer including a first winding and a second winding; and a connection element connected between the first winding and the second winding of the transformer; the method for detecting and locating of insulation state including:

step S1, changing a state of at least one switch in the conversion system, such that a voltage applied between the first winding and the second winding of the transformer in at least one of the n conversion units changes;

step S2, detecting a value reflecting a current flowing through the connection element before change of the state of the at least one switch and a value reflecting a current flowing through the connection element after change of the state of the at least one switch, respectively; and

step S3, comparing the value reflecting the current flowing through the connection element before change of the state of the at least one switch with the value reflecting the current flowing through the connection element after change of the state of the at least one switch, and determining which of the n conversion units has insulation abnormality based on comparison result.

In order to achieve the object, the invention further provides a device for detecting and locating insulation state of a conversion system, the conversion system including: a converter module including n conversion units, where n≥2, each conversion unit including a transformer including a first winding and a second winding; and a connection element connected between the first winding and the second winding of the transformer; the device for detecting and locating of insulation state including: a control unit connected to the converter module for changing a state of at least one switch in the conversion system, such that a voltage applied between the first winding and the second winding of the transformer in at least one of the n conversion units changes; an insulation detecting unit nested onto the connection element and connected to the control unit for detecting a value reflecting a current flowing through the connection element before change of the state of the at least one switch and a value reflecting a current flowing through the connection element after change of the state of the at least one switch, respectively; and a processing unit connected to the insulation detecting unit for comparing the value reflecting the current flowing the connection element before change of the state of the at least one switch with the value reflecting the current flowing the connection element after change of the state of the at least one switch, and determining which of the n conversion units has insulation abnormality based on comparison result.

The invention provides a method and device for detecting and locating of insulation state of a conversion system, which can locate position of modules that have insulation abnormality in the conversion system, simplifies fault maintenance work, and reduces maintenance cost.

### BRIEF DESCRIPTION OF THE DRAWINGS

To clearly explain the technical solution implemented by the invention, hereinafter the accompanying drawings used in the embodiments are simply introduced.

FIG. 1 is a structural diagram of a device for detecting and locating insulation state of a conversion system in example one of the invention.

FIG. 2 is a flow diagram I of a method for detecting and locating insulation state in example one.

FIG. 3 is a flow diagram II of a method for detecting and locating insulation state in example one.

FIG. 4 is a flow diagram III of a method for detecting and locating insulation state in example one.

FIG. 5 is a structural diagram of a device for detecting and locating insulation state for a conversion system in example two of the invention.

FIG. 6 is a flow diagram I of a method for detecting and locating insulation state in example two.

FIG. 7 is a flow diagram II of a method for detecting and locating insulation state in example two.

FIG. 8 is a flow diagram III of a method for detecting and locating insulation state in example two.

FIG. 9 is a structural diagram of conversion units in the device for detecting and locating insulation state of a conversion system in example two.

FIG. 10 is a flow diagram IV of a method for detecting and locating insulation state in example two.

FIG. 11 is a flow diagram V of a method for detecting and locating insulation state in example two.

FIG. 12 is a flow diagram VI of a method for detecting and locating insulation state in example two.

FIG. 13 is a structural diagram of a device for detecting and locating insulation state for a conversion system in example three of the invention.

FIG. 14 is a flow diagram I of a method for detecting and locating insulation state in example three.

FIG. 15 is a flow diagram II of a method for detecting and locating insulation state in example three.

### DETAILED EMBODIMENTS OF THE INVENTION

The exemplary implementations will now be described more fully with reference to the accompanying drawings. However, the exemplary implementations can be implemented in various forms and should not be understood as being limited to the implementations set forth herein; on the contrary, these implementations are provided so that this invention will be thorough and complete, and the conception of exemplary implementations will be fully conveyed to those skilled in the art.

When introducing the described and/or illustrated factors or components or the like, the words “one”, “first”, “the” and “at least one” represent one or more factors or components, or the like. The terms “comprise”, “include” and “have” represent an open and including meaning, and refer to other factors or components, or the like, except listed factors or components, or the like. Moreover, the terms “first”, “second” and the like in the claims are only used as signs, instead of limiting the numbers of the object. The same number in the drawings represents the same or similar assembly. On the other hand, the well-known assemblies and steps are not described in the embodiments in order to avoid unnecessary limit to the invention. Moreover, for sake of simplifying the drawings, some known customary structures and elements are shown in a simple illustration way in the drawings. Finally, “couple” or “connection” used in the disclosure may refer to that two or more elements are in direct physical contact or electrical contact, or in indirect physical contact or electrical contact.

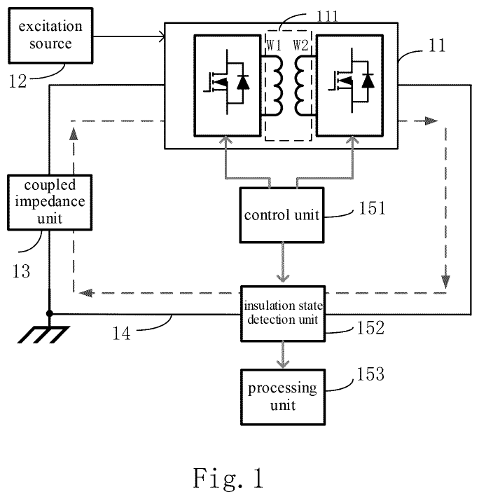

FIG. 1 is a structural diagram of a device for detecting and locating insulation state of a conversion system in example one of the invention. As shown in FIG. 1, the conversion system includes a converter module 11 including n conversion units, where n≥1, each conversion unit including a transformer 111 including a first winding W1 and a second winding W2, an excitation source 12 electrically connected to the first winding W1 of the transformer 111, a connection element 14 connected between the first winding W1 and the second winding W2 of the transformer 111, and a coupled impedance unit 13 connected in series to the connection element 14, and having a ground end connected to the connection element 14. In some other embodiments, the excitation source 12 is electrically connected to the second winding W2 of the transformer 111. In some embodiments, the connection element 14 is a cable or PCB routing or sheet metal part with low impedance. In some embodiments, the connection element 14 may include a switch, such as, a converter.

The device for detecting and locating insulation state includes a control unit 151 connected to the converter module 11 for changing a state of at least one switch in the conversion system, such that a voltage applied between the first winding W1 and the second winding W2 of the transformer 111 in at least one of the n conversion units changes, an insulation state detection unit 152 nested onto the connection element 14 and connected to the control unit 151 for detecting a value reflecting a current flowing through the connection element 14 before change of the state of the at least one switch and a value reflecting a current flowing through the connection element 14 after change of the state of the at least one switch, respectively, and a processing unit 153 connected to the insulation state detection unit 152 for comparing the value reflecting a current flowing through the connection element 14 before change of the state of the at least one switch with the value reflecting a current flowing through the connection element 14 after change of the state of the at least one switch, and determining which of the n conversion units has insulation abnormality based on comparison result. In some other embodiments, the insulation state detection unit 152 shall only have electrical or magnetic association with the connection element 14 to detect a value reflecting a current flowing through the connection element 14 without being nested onto the connection element 14.

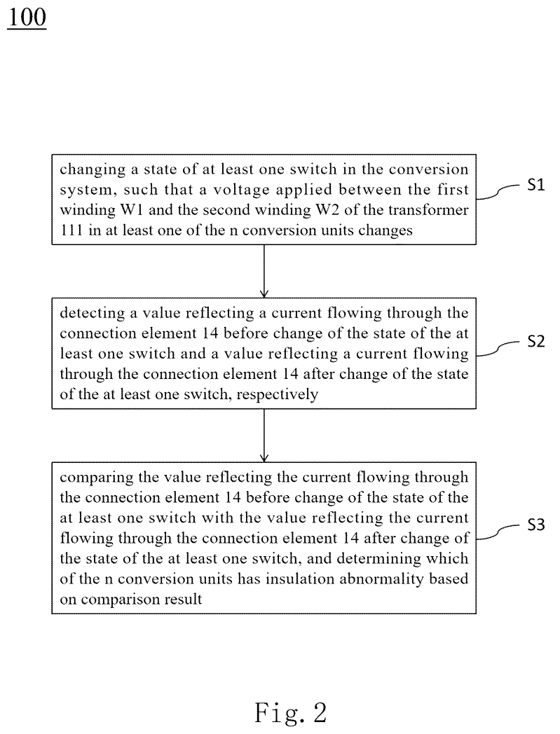

FIG. 2 is a flow diagram of a method 100 for detecting and locating insulation state of the device shown in FIG. 1. Referring to FIGS. 1 and 2, the method 100 for detecting and locating insulation state includes:
step S1, changing a state of at least one switch in the conversion system, such that a voltage applied between the first winding W1 and the second winding W2 of the transformer 111 in at least one of the n conversion units changes;
step S2, detecting a value reflecting a current flowing through the connection element 14 before change of the state of the at least one switch and a value reflecting a current flowing through the connection element 14 after change of the state of the at least one switch, respectively; and
step S3, comparing the value reflecting the current flowing through the connection element 14 before change of the state of the at least one switch with the value reflecting the current flowing through the connection element 14 after change of the state of the at least one switch, and determining which of the n conversion units has insulation abnormality based on comparison result.

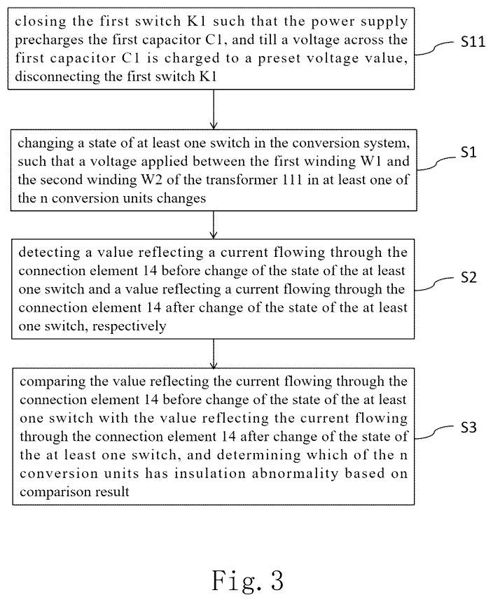

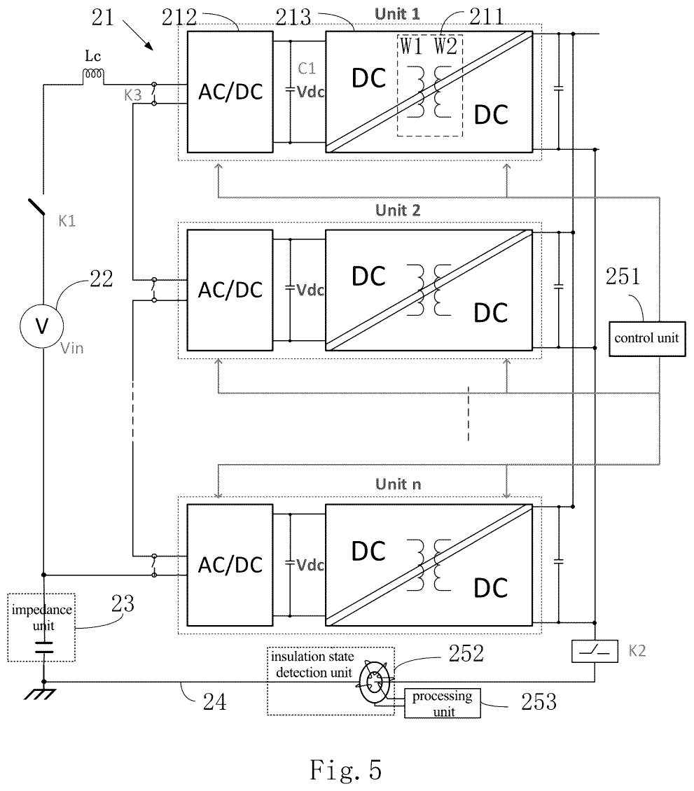

Further, in another embodiment of the invention, as shown in FIG. 5, the conversion system may further include a first switch K1 connected between the excitation source 22 and an input port of the converter module 21, and each conversion unit further includes a first capacitor C1. As shown in FIG. 3, before the step S1, the method 100 for detecting and locating insulation state further includes:
step S11, closing the first switch K1 such that the power supply precharges the first capacitor C1, and till a voltage across the first capacitor C1 is charged to a preset voltage value, disconnecting the first switch K1.

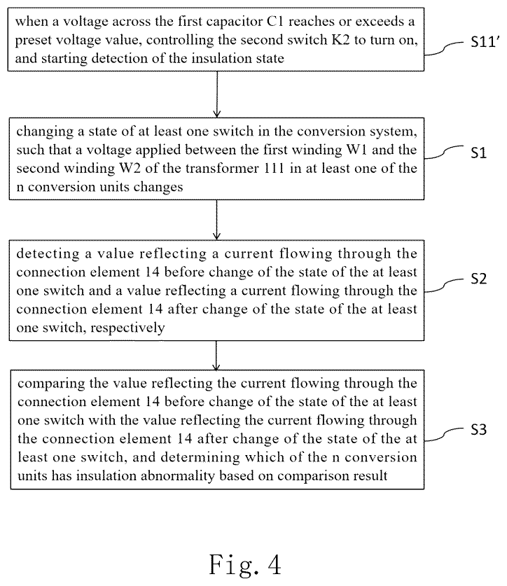

In another embodiment of the invention, as shown in FIG. 5, the conversion system may further include a second switch K2 connected in series with the connection element 24, and each conversion unit further includes a first capacitor C1. As shown in FIG. 4, before the step S1, the method 100 for detecting and locating insulation state further includes:
step S11′, when a voltage across the first capacitor C1 reaches or exceeds a preset voltage value, controlling the second switch K2 to turn on, and starting detection of the insulation state.

FIG. 5 is a structural diagram of a device for detecting and locating insulation state of a conversion system in example two of the invention. As shown in FIG. 5, the conversion system includes a converter module 21 including n conversion units (Unit 1, Unit 2, . . . , Unit n), where n≥1, each conversion unit including a transformer 211 including a first winding W1 and a second winding W2, an excitation source 22 (a power supply Vin), a coupled impedance unit 23 (such as, a capacitor), a connection element 24, a first switch K1 and a second switch K2. Each conversion unit further includes an AC/DC converter 212, a DC/AC converter 213 and a first capacitor C1. The AC/DC converter 212, the DC/AC converter 213 and the transformer 211 are electrically connected sequentially. The first capacitor C1 is connected in parallel to a DC side of the AC/DC converter 212, AC sides of the AC/DC converters 212 of the first conversion unit Unit 1 to the n-th conversion unit Unit n are connected in series sequentially, and a voltage across both ends of the first capacitor C1 is Vdc. The excitation source 22 is electrically connected to the first winding W1 of the transformer 211, the connection element 24 is connected between the first winding W1 and the second winding W2 of the transformer 211, and the coupled impedance unit 23 is connected in series to the connection element 24, and has a ground end connected to the connection element 24.

The device for detection and location of insulation state includes a control unit 251, an insulation state detection unit 252 (such as, a current transducer) and a processing unit 253. The control unit 251, the insulation state detection unit 252 and the processing unit 253 have the same structure and function as that shown in FIG. 1, so the details are not described here.

Firstly, the first switch K1 of the conversion system is closed to precharge the first capacitor C1 using the power supply Vin, till a voltage across the first capacitor C1 is charged to a preset voltage value, the first switch K1 is disconnected, the second switch K2 is controlled to turn on, and detection of insulation state starts. In some embodiments, before insulation detection starts, the voltage across the first capacitor C1 has been greater than the preset value, for example, when the conversion system is just switched from a running state to a shutdown state, the voltage across the DC capacitor is still greater than the preset value, so it is unnecessary to precharge.

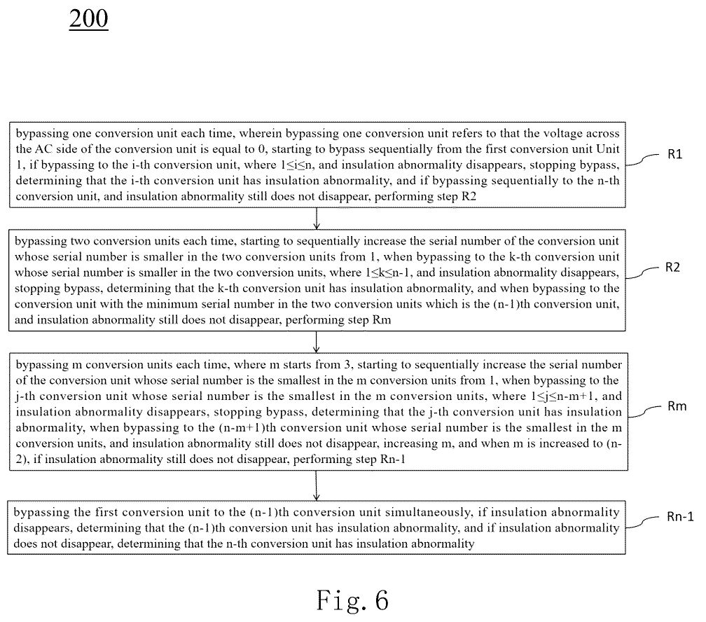

FIG. 6 shows a method 200 for detecting and locating insulation state of a conversion system provided in example two of the invention, and positions of the conversion units that have insulation abnormality are located by reducing excitation of the voltage across the transformer to be detected according to phenomenon of disappearing of insulation abnormality. Combining with FIGS. 5 and 6, when absolute values of voltages across the AC sides of the AC/DC converters 212 of the n conversion units are Vdc, if the conversion system has insulation abnormality, the method 200 for detecting and locating insulation state includes:
step R1, bypassing one conversion unit each time, wherein bypassing one conversion unit refers to that the voltage across the AC side of the conversion unit is equal to 0, starting to bypass sequentially from the first conversion unit Unit 1, if bypassing to the i-th conversion unit, where 1≤i≤n, and insulation abnormality disappears, stopping bypass, determining that the i-th conversion unit has insulation abnormality, and if bypassing sequentially to the n-th conversion unit, and insulation abnormality still does not disappear, performing step R2;
step R2, bypassing two conversion units each time, starting to sequentially increase the serial number of the conversion unit whose serial number is smaller in the two conversion units from 1, when bypassing to the k-th conversion unit whose serial number is smaller in the two conversion units, where 1≤k≤n−1, and insulation abnormality disappears, stopping bypass, determining that the k-th conversion unit has insulation abnormality, and when bypassing to the conversion unit with the minimum serial number in the two conversion units which is the (n−1)th conversion unit, and insulation abnormality still does not disappear, performing step Rm;
step Rm, bypassing m conversion units each time, where m starts from 3, starting to sequentially increase the serial number of the conversion unit whose serial number is the smallest in the m conversion units from 1, when bypassing to the j-th conversion unit whose serial number is the smallest in the m conversion units, where 1≤j≤n−m+1, and insulation abnormality disappears, stopping bypass, determining that the j-th conversion unit has insulation abnormality, when bypassing to the (n−m+1)th conversion unit whose serial number is the smallest in the m conversion units, and insulation abnormality still does not disappear, increasing m, and when m is increased to (n−2), if insulation abnormality still does not disappear, performing step Rn−1; and
step Rn−1, bypassing the first conversion unit to the (n−1)th conversion unit simultaneously, if insulation abnormality disappears, determining that the (n−1)th conversion unit has insulation abnormality, and if insulation abnormality does not disappear, determining that the n-th conversion unit has insulation abnormality.

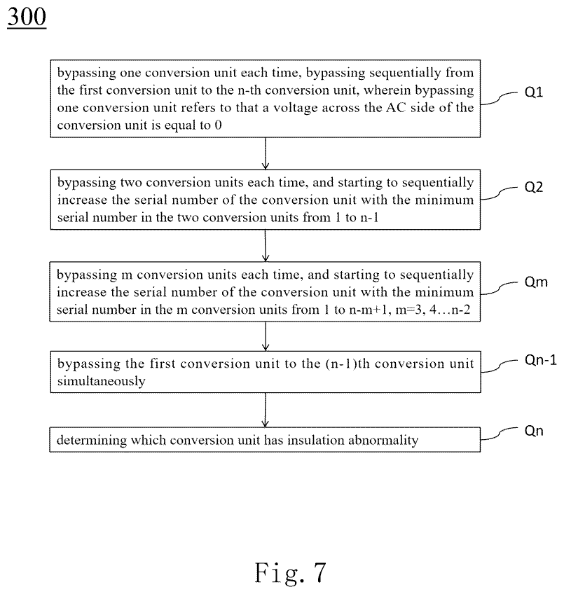

FIG. 7 is a method 300 for detecting and locating insulation state of a conversion system provided in example two of the invention. Combining with FIGS. 5 and 7, when absolute values of voltages across the AC sides of the AC/DC converters 213 of the n conversion units are Vdc, if the conversion system has insulation abnormality, the method 300 for detecting and locating insulation state includes:
step Q1, bypassing one conversion unit each time, bypassing sequentially from the first conversion unit to the n-th conversion unit, wherein bypassing one conversion unit refers to that a voltage across the AC side of the conversion unit is equal to 0;
step Q2, bypassing two conversion units each time, and starting to sequentially increase the serial number of the conversion unit with the minimum serial number in the two conversion units from 1 to n−1;
step Qm, bypassing m conversion units each time, and starting to sequentially increase the serial number of the conversion unit with the minimum serial number in the m conversion units from 1 to n−m+1, m=3, 4 . . . n−2;
step Qn−1, bypassing the first conversion unit to the (n−1)th conversion unit simultaneously; and
step Qn, determining which conversion unit has insulation abnormality.

Referring to FIG. 5, the AC side of the AC/DC converter 212 of each conversion unit is connected in parallel to a third switch K3, and the corresponding conversion unit is bypassed by turning on the third switch K3, such that a voltage across the AC side of the conversion unit is equal to 0.

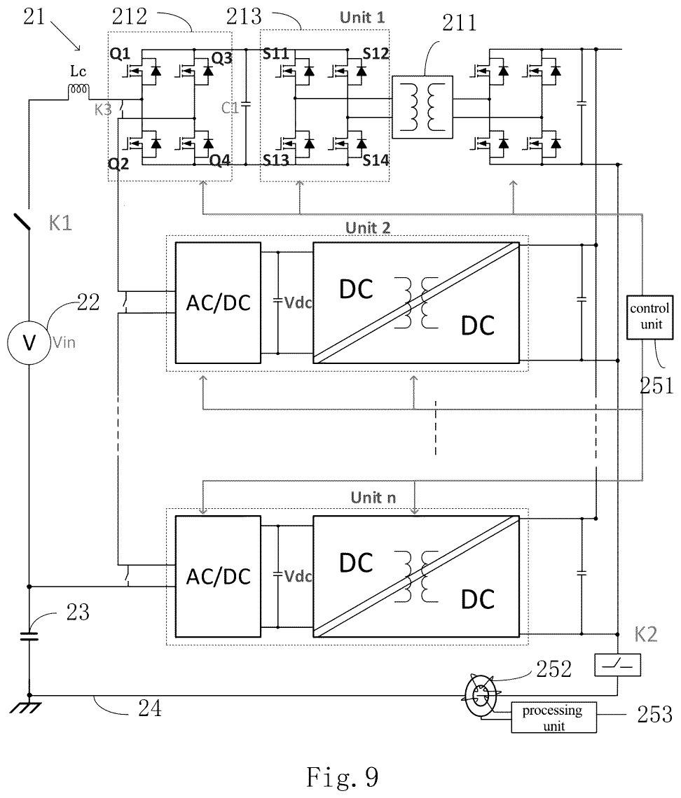

In other embodiments, the corresponding conversion unit can also be bypassed by controlling a state of switching tubes in the AC/DC converter 212. As shown in FIG. 9, the conversion system includes a converter module 21 including n conversion units (Unit 1, Unit 2, . . . , Unit n), where n≥1, and each conversion unit further includes an AC/DC converter 212, a DC/AC converter 213 and a transformer electrically connected sequentially. The AC/DC converter 212 uses a full bridge circuit, and includes upper switching tubes Q1, Q3 and lower switching tubes Q2, Q4. The corresponding conversion unit is bypassed by turning on all upper switches tubes Q1, Q3 of the AC/DC converter 212. The switches of the converter are one of power switching devices such as MOSFET, IGBT or IGCT. Since the switching devices generate interference signals at the moment of switching from an off state to an on state or from an on state to an off state, in order to avoid influence of the interference signal on insulation detection, in some embodiments, the control unit 251 shields the insulation detection signal at the moment of switching the switching devices, and is responsive to the insulation detection signal when the switching devices are stably turned on or turned off.

In some embodiments, all steps of insulation and location and the sequences of bypassing the conversion units may be changed.

For example, m conversion units may be bypassed each time, and other (n−m) conversion units are in an input state, where m may be taken from 1 to n. The m conversion units are bypassed from n conversion units, which are totally Cm bypass combinations, and all bypass combinations are completed.

In such way, after all bypass combinations including bypassing one conversion unit, two conversion units, . . . , and n conversion units each time are completed, it may be determined which conversion unit has insulation abnormality based on comparison of all bypass combinations.

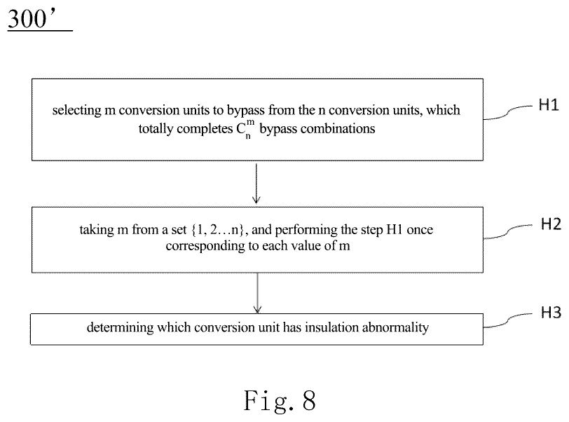

FIG. 8 is a method 300′ for detecting and locating insulation state of a conversion system provided in example two of the invention. Combining with FIGS. 5 and 8, when absolute values of voltages across the AC sides of the AC/DC converters of the n conversion units are Vdc, the method 300′ for detecting and locating insulation state includes:
step H1, selecting m conversion units to bypass from the n conversion units, which totally completes Cm bypass combinations;
step H2, taking m from a set {1, 2 . . . n}, and performing the step H1 once corresponding to each value of m; and
step H3, determining which conversion unit has insulation abnormality.

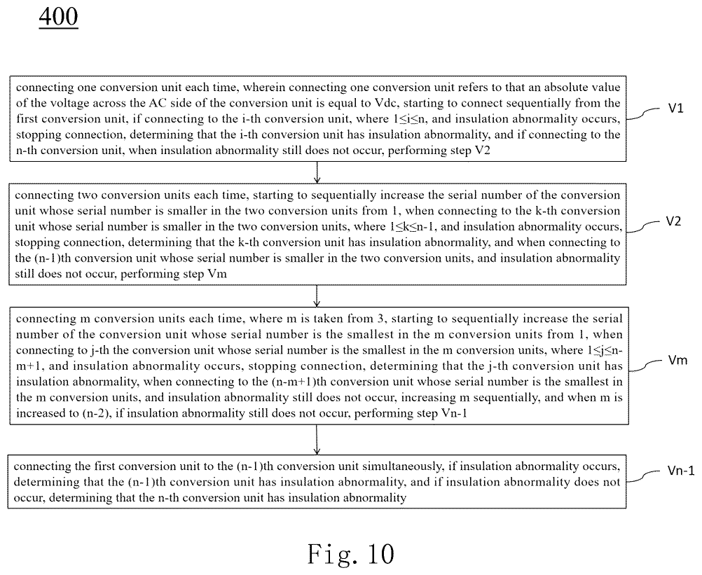

FIG. 10 shows a method 400 for detecting and locating insulation state of a conversion system provided in example two of the invention, and positions of the conversion units that have insulation abnormality are located by increasing excitation of the voltage across the transformer to be detected according to phenomenon of occurrence of insulation abnormality. Combining with FIGS. 5 and 10, when voltages across the AC/DC converters of the n conversion units are all 0, the method 400 for detecting and locating insulation state includes:
step V1, connecting one conversion unit each time, wherein connecting one conversion unit refers to that an absolute value of the voltage across the AC side of the conversion unit is equal to Vdc, starting to connect sequentially from the first conversion unit, if connecting to the i-th conversion unit, where 1≤i≤n, and insulation abnormality occurs, stopping connection, determining that the i-th conversion unit has insulation abnormality, and if connecting to the n-th conversion unit, when insulation abnormality still does not occur, performing step V2;
step V2, connecting two conversion units each time, starting to sequentially increase the serial number of the conversion unit whose serial number is smaller in the two conversion units from 1, when connecting to the k-th conversion unit whose serial number is smaller in the two conversion units, where 1≤k≤n−1, and insulation abnormality occurs, stopping connection, determining that the k-th conversion unit has insulation abnormality, and when connecting to the (n−1)th conversion unit whose serial number is smaller in the two conversion units, and insulation abnormality still does not occur, performing step Vm;
step Vm, connecting m conversion units each time, where m is taken from 3, starting to sequentially increase the serial number of the conversion unit whose serial number is the smallest in the m conversion units from 1, when connecting to j-th the conversion unit whose serial number is the smallest in the m conversion units, where 1≤j≤n−m+1, and insulation abnormality occurs, stopping connection, determining that the j-th conversion unit has insulation abnormality, when connecting to the (n−m+1)th conversion unit whose serial number is the smallest in the m conversion units, and insulation abnormality still does not occur, increasing m sequentially, and when m is increased to (n−2), if insulation abnormality still does not occur, performing step Vn−1; and
step Vn−1, connecting the first conversion unit to the (n−1)th conversion unit simultaneously, if insulation abnormality occurs, determining that the (n−1)th conversion unit has insulation abnormality, and if insulation abnormality does not occur, determining that the n-th conversion unit has insulation abnormality.

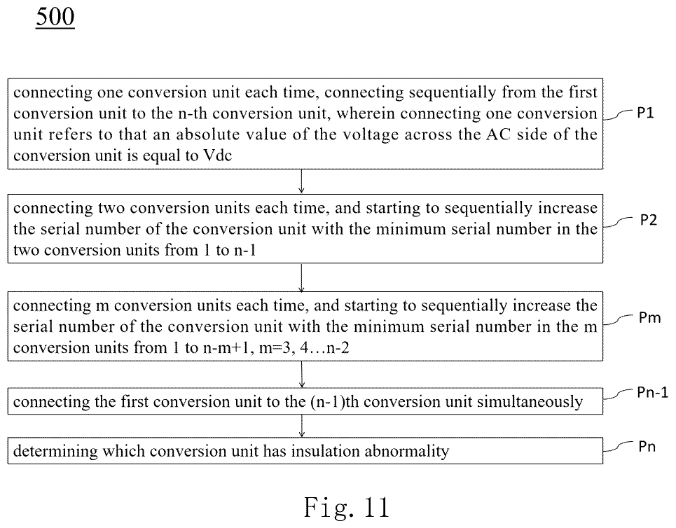

FIG. 11 is a method 500 for detecting and locating insulation state of a conversion system provided in example two of the invention. Combining with FIGS. 5 and 11, when absolute values of voltages across the AC sides of the AC/DC converters 213 of the n conversion units are all 0, the method 500 for detecting and locating insulation state includes:
step P1, connecting one conversion unit each time, connecting sequentially from the first conversion unit to the n-th conversion unit, wherein connecting one conversion unit refers to that an absolute value of the voltage across the AC side of the conversion unit is equal to Vdc;
step P2, connecting two conversion units each time, and starting to sequentially increase the serial number of the conversion unit with the minimum serial number in the two conversion units from 1 to n−1;
step Pm, connecting m conversion units each time, and starting to sequentially increase the serial number of the conversion unit with the minimum serial number in the m conversion units from 1 to n−m+1, m=3, 4 . . . n−2;
step Pn−1, connecting the first conversion unit to the (n−1)th conversion unit simultaneously; and
step Pn, determining which conversion unit has insulation abnormality.

In some embodiments, all steps of insulation and location and the sequences of inputting the conversion units may be changed.

For example, m conversion units may be connected each time, and other (n−m) conversion units are in a bypass state, where m may start from 1 to n. The m conversion units are connected from the n conversion units, which are totally Cm connecting combinations, and all connecting combinations are completed.

In such way, after all connecting combinations including connecting one conversion unit, two conversion units, . . . , and n conversion units each time are completed, it may be determined which conversion unit has insulation abnormality based on comparison of all connecting combinations.

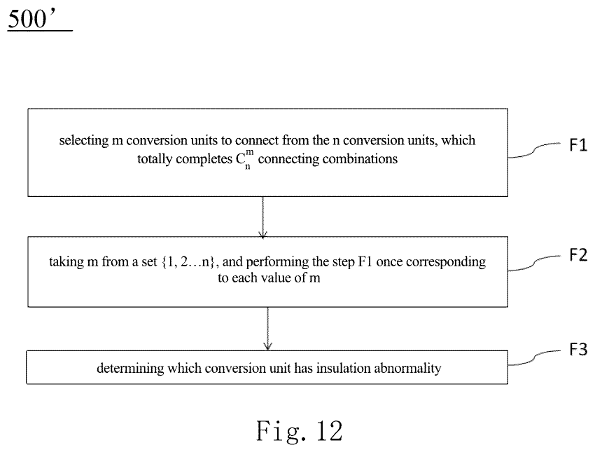

FIG. 12 is a method 500′ for detecting and locating insulation state of a conversion system provided in example two of the invention. Combining with FIGS. 5 and 12, when absolute values of voltages across the AC sides of the AC/DC converters of the n conversion units are all 0, the method 500′ for detecting and locating insulation state includes:
step F1, selecting m conversion units to connect from the n conversion units, which totally completes Cm connecting combinations;
step F2, taking m from a set {1, 2 . . . n}, and performing the step F1 once corresponding to each value of m; and
step F3, determining which conversion unit has insulation abnormality.

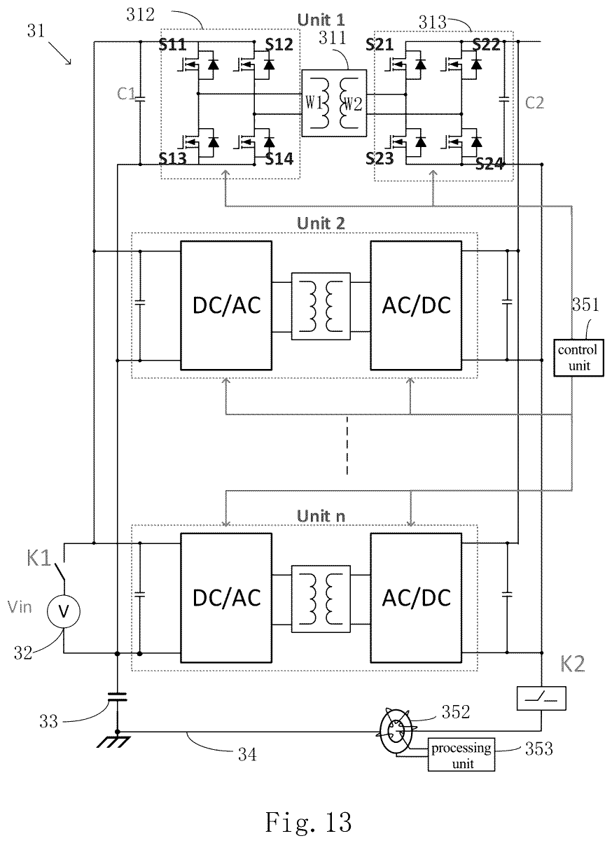

FIG. 13 is a structural diagram of a device for detecting and locating insulation state of a conversion system provided in example three of the invention. As shown in FIG. 13, the conversion system includes a conversion module 31 including n conversion units (Unit 1, Unit 2, . . . , Unit n), where n≥1, each conversion unit including a transformer 311 including a first winding W1 and a second winding W2, an excitation source 32 (a power supply Vin), a coupled impedance unit 33, a connection element 34, a first switch K1 and a second switch K2. Each conversion unit further includes a DC/AC converter 312, an AC/DC converter 313, a first capacitor C1 connected in parallel to a DC side of the DC/AC converter 312, and a second capacitor C2 connected in parallel to a DC side of the AC/DC converter 313. The DC/AC converter 312, the transformer 311 and the AC/DC converter 313 are electrically connected sequentially. The first winding W1 and the DC/AC converter 312 are electrically connected, and the second winding W2 and the AC/DC converter 313 are electrically connected. The DC sides of the DC/AC converters 312 of the n conversion units are connected in parallel, and the DC sides of the AC/DC converters 313 of the n conversion units are connected in parallel. The excitation source 32 is electrically connected to the first winding W1 of the transformer 311, the connection element 34 is connected between the first winding W1 and the second winding W2 of the transformer 311, and the coupled impedance unit 33 is connected in series to the connection element 34, and has a ground end connected to the connection element 34.

In some embodiments, the DC sides of the DC/AC converters 312 of the n conversion units may also be in a series connection form.

In this embodiment, the device for detection and location of insulation state includes a control unit 351, an insulation detecting unit 352 and a processing unit 353. The control unit 351, the insulation detecting unit 352 and the processing unit 353 have the same structure and function as that shown in FIG. 1, so the details are not described here.

In one embodiment of example three of the invention, firstly, the first winding W1 of each conversion unit is connected to a positive terminal of the first capacitor C1 of the corresponding conversion unit, and the second winding W2 of each conversion unit is connected to a negative terminal of the second capacitor C2 of the corresponding conversion unit through the control unit.

Continue to refer to FIG. 13, the DC/AC converter 312 and the AC/DC converter 313 in each conversion unit both use full bridge circuits. The DC/AC converter 312 includes upper switches S11, S12 and lower switches S13, S14. The AC/DC converter 313 includes upper switches S21, S22 and lower switches S23, S24, the corresponding first winding W1 of the DC/AC converter 312 is connected to a positive terminal of the first capacitor C1 by turning on all upper switches of the DC/AC converter 312, and the corresponding second winding W2 of the AC/DC converter 313 is connected to a negative terminal of the second capacitor C2 by turning on all lower switches of the AC/DC converter 313.

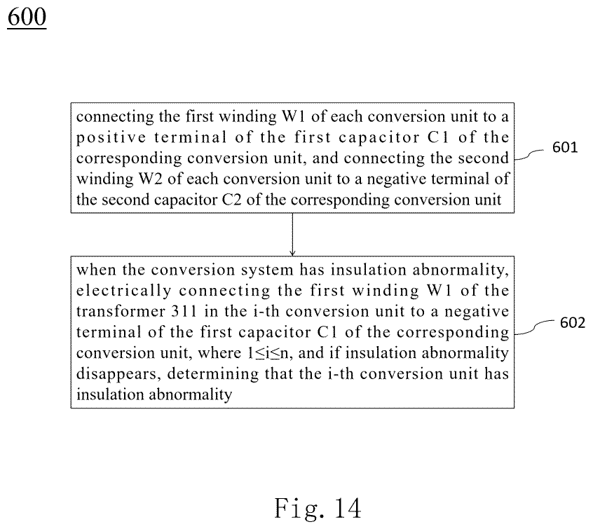

FIG. 14 shows a method 600 for detecting and locating insulation state of a conversion system provided in example three of the invention, and positions of the conversion units that have insulation abnormality are located by reducing excitation of the voltage across the transformer to be detected according to phenomenon of disappearing of insulation abnormality. The method 600 for detecting and locating insulation state includes:
601: connecting the first winding W1 of each conversion unit to a positive terminal of the first capacitor C1 of the corresponding conversion unit, and connecting the second winding W2 of each conversion unit to a negative terminal of the second capacitor C2 of the corresponding conversion unit;
602: when the conversion system has insulation abnormality, electrically connecting the first winding W1 of the transformer 311 in the i-th conversion unit to a negative terminal of the first capacitor C1 of the corresponding conversion unit, where 1≤i≤n, and if insulation abnormality disappears, determining that the i-th conversion unit has insulation abnormality.

In another embodiment of example three of the invention, firstly, the first winding of each conversion unit is connected to a negative terminal of the first capacitor of the corresponding conversion unit, and the second winding of each conversion unit is connected to a negative terminal of the second capacitor of the corresponding conversion unit through the control unit, i.e., turning on all lower switches S13, S14 of the DC/AC converter 312 such that the corresponding first winding W1 of the DC/AC converter 312 is connected to a negative terminal of the first capacitor C1, and turning on all lower switches S23, S24 of the AC/DC converter 313 such that the corresponding second winding W2 of the AC/DC converter 313 is connected to a negative terminal of the second capacitor C2.

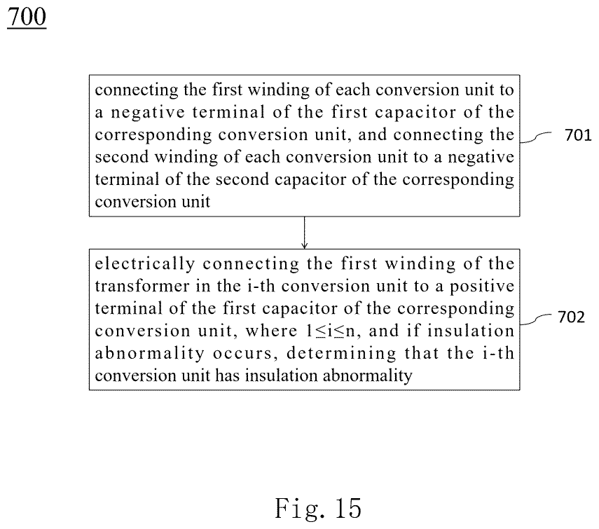

FIG. 15 shows a method 700 for detecting and locating insulation state of a conversion system provided in example three of the invention, and positions of the conversion units that have insulation abnormality are located by increasing excitation of the voltage across the transformer to be detected according to phenomenon of occurrence of insulation abnormality. The method 700 for detecting and locating insulation state includes:
701: connecting the first winding of each conversion unit to a negative terminal of the first capacitor of the corresponding conversion unit, and connecting the second winding of each conversion unit to a negative terminal of the second capacitor of the corresponding conversion unit;
702: electrically connecting the first winding of the transformer in the i-th conversion unit to a positive terminal of the first capacitor of the corresponding conversion unit, where 1≤i≤n, and if insulation abnormality occurs, determining that the i-th conversion unit has insulation abnormality.

To sum up, the invention provides a method for detecting and locating insulation state of a conversion system, the conversion system including: a converter module including n conversion units, where n≥2, each conversion unit including a transformer including a first winding and a second winding; and a connection element connected between the first winding and the second winding of the transformer; the method for detecting and locating insulation state including:
step S1, changing a state of at least one switch in the conversion system, such that a voltage applied between the first winding and the second winding of the transformer in at least one of the n conversion units changes;
step S2, detecting a value reflecting a current flowing through the connection element before change of the state of the at least one switch and a value reflecting a current flowing through the connection element after change of the state of the at least one switch, respectively; and
step S3, comparing the value reflecting the current flowing through the connection element before change of the state of the at least one switch with the value reflecting the current flowing through the connection element after change of the state of the at least one switch, and determining which of the n conversion units has insulation abnormality based on comparison result.

The invention further provides a device for detecting and locating insulation state of a conversion system, the conversion system including: a converter module including n conversion units, where n≥2, each conversion unit including a transformer including a first winding and a second winding; and a connection element connected between the first winding and the second winding of the transformer; the device for detecting and locating insulation state including: a control unit connected to the converter module for changing a state of at least one switch in the conversion system, such that a voltage applied between the first winding and the second winding of the transformer in at least one of the n conversion units changes; an insulation detecting unit nested onto the connection element and connected to the control unit for detecting a value reflecting a current flowing the connection element before change of the state of the at least one switch and a value reflecting a current flowing the connection element after change of the state of the at least one switch, respectively; and a processing unit connected to the insulation detecting unit for comparing the value reflecting the current flowing the connection element before change of the state of the at least one switch with the value reflecting the current flowing the connection element after change of the state of the at least one switch, and determining which of the n conversion units has insulation abnormality based on comparison result.

By adjusting the state of switches in the conversion system and adjusting insulation state of the corresponding conversion unit to test excitation voltage value in the insulation state detection system of the conventional medium-high converter, and locating position of the conversion units that have insulation abnormality through change of the insulation state detection signal of the conversion system, the invention has the following advantages:
(1) being widely applied to local detection of the multi-module medium-high isolation converter;
(2) assisting in simplifying fault maintenance work, and reducing maintenance cost;
(3) being easy to implement, and having a low cost without additionally adding components.

Although the embodiments of the invention have been illustrated and described, as for those ordinary in the art, it can be understood that these embodiments can have various changes, modifications, replacements and variations without departing from principle and spirit of the invention, and the protection scope of the invention is determined by the scope defined by the appended claims.

What is claimed is:

1. A method for detecting and locating insulation state of a conversion system, the conversion system comprising:
a converter module comprising n conversion units, where n≥2, each conversion unit comprising a transformer comprising a first winding and a second winding; and
a connection element connected between the first winding and the second winding of the transformer; the method for detecting and locating insulation state comprising:
step S1, changing a state of at least one switch in the conversion system, such that a voltage applied between the first winding and the second winding of the transformer in at least one of the n conversion units changes;
step S2, detecting a value reflecting a current flowing through the connection element before change of the state of the at least one switch and a value reflecting a current flowing through the connection element after change of the state of the at least one switch, respectively; and
step S3, comparing the value reflecting the current flowing through the connection element before change of the state of the at least one switch with the value reflecting the current flowing through the connection element after change of the state of the at least one switch, and determining which of the n conversion units has insulation abnormality based on comparison result.

2. The method for detecting and locating insulation state according to claim 1, wherein the conversion system further comprises a first switch connected between a power supply and an input end of the converter module, and each conversion unit comprises a first capacitor, before the step S1, the method further comprising:
step S11, closing the first switch such that the power supply precharges the first capacitor, and till a voltage of the first capacitor is charged to a preset voltage value, disconnecting the first switch.

3. The method for detecting and locating insulation state according to claim 1, wherein the conversion system further comprises a second switch connected in series with the connection element, and each conversion unit comprises a first capacitor, before the step S1, the method further comprising:
step S11, when a voltage of the first capacitor reaches or exceeds a preset voltage value, controlling the second switch to turn on, and starting detection of the insulation state.

4. The method for detecting and locating insulation state according to claim 1, wherein the n conversion units comprise a first conversion unit to a n-th conversion unit, each conversion unit further comprises an AC/DC converter, a DC/AC converter and a first capacitor connected in parallel to a DC side of the AC/DC converter, the AC/DC converter, the DC/AC converter and the transformer are electrically connected sequentially, AC sides of the AC/DC converters of the first conversion unit to the n-th conversion unit are connected in series sequentially, a voltage across the first capacitor is Vdc, and when absolute values of voltages across the AC sides of the AC/DC converters of the n conversion units are all Vdc, if the conversion system has insulation abnormality, the method for detecting and locating insulation state comprises:
step R1, bypassing one conversion unit each time, wherein bypassing one conversion unit refers to that the voltage across the AC side of the conversion unit is equal to 0, starting to bypass sequentially from the first conversion unit, if bypassing to the i-th conversion unit, where 1≤i≤n, and insulation abnormality disappears, stopping bypass, determining that the i-th conversion unit has insulation abnormality, and if bypassing sequentially to the n-th conversion unit, and insulation abnormality still does not disappear, performing step R2;
step R2, bypassing two conversion units each time, starting to sequentially increase the serial number of the conversion unit whose serial number is smaller in the two conversion units from 1, when bypassing to the k-th conversion unit whose serial number is smaller in the two conversion units, where 1≤k≤−1, and insulation abnormality disappears, stopping bypass, determining that the k-th conversion unit has insulation abnormality, and when bypassing to the conversion unit with the minimum serial number in the two conversion units which is the (n−1)th conversion unit, and insulation abnormality still does not disappear, performing step Rm;
step Rm, bypassing m conversion units each time, where m starts from 3, starting to sequentially increase the serial number of the conversion unit whose serial number is the smallest in the m conversion units from 1, when bypassing to the j-th conversion unit whose serial number is the smallest in the m conversion units, where 1≤j≤n−m+1, and insulation abnormality disappears, stopping bypass, determining that the j-th conversion unit has insulation abnormality, when bypassing to the (n−m+1)th conversion unit whose serial number is the smallest in the m conversion units, and insulation abnormality still does not disappear, increasing m, and when m is increased to (n−2), if insulation abnormality still does not disappear, performing step Rn−1; and
step Rn−1, bypassing the first conversion unit to the (n−1)th conversion unit simultaneously, if insulation abnormality disappears, determining that the (n−1)th conversion unit has insulation abnormality, and if insulation abnormality does not disappear, determining that the n-th conversion unit has insulation abnormality.

5. The method for detecting and locating insulation state according to claim 1, wherein the n conversion units comprise a first conversion unit to a n-th conversion unit, each conversion unit further comprises an AC/DC converter, a DC/AC converter and a first capacitor connected in parallel to a DC side of the AC/DC converter, the AC/DC converter, the DC/AC converter and the transformer are electrically connected sequentially, AC sides of the AC/DC converters of the first conversion unit to the n-th conversion unit are connected in series sequentially, a voltage across the first capacitor is Vdc, and when absolute values of voltages across the AC sides of the AC/DC converters of the n conversion units are all Vdc, if the conversion system has insulation abnormality, the method for detecting and locating insulation state comprises:
step Q1, bypassing one conversion unit each time, bypassing sequentially from the first conversion unit to the n-th conversion unit, wherein bypassing one conversion unit refers to that a voltage across the AC side of the conversion unit is equal to 0;
step Q2, bypassing two conversion units each time, and starting to sequentially increase the serial number of the conversion unit with the minimum serial number in the two conversion units from 1 to n−1;
step Qm, bypassing m conversion units each time, and starting to sequentially increase the serial number of the conversion unit with the minimum serial number in the m conversion units from 1 to n−m+1, m=3, 4 . . . n−2;
step Qn−1, bypassing the first conversion unit to the (n−1)th conversion unit simultaneously; and
step Qn, determining which conversion unit has insulation abnormality.

6. The method for detecting and locating insulation state according to claim 1, wherein the n conversion units comprise a first conversion unit to a n-th conversion unit, each conversion unit further comprises an AC/DC converter, a DC/AC converter and a first capacitor connected in parallel to a DC side of the AC/DC converter, the AC/DC converter, the DC/AC converter and the transformer are electrically connected sequentially, AC sides of the AC/DC converters of the first conversion unit to the n-th conversion unit are connected in series sequentially, a voltage across the first capacitor is Vdc, and when absolute values of voltages across the AC sides of the AC/DC converters of the n conversion units are all Vdc, if the conversion system has insulation abnormality, the method for detecting and locating insulation state comprises:
step H1, selecting m conversion units to bypass from the n conversion units, which totally completes Cn bypass combinations;
step H2, taking m from a set {1, 2 . . . n}, and performing the step H1 once corresponding to each value of m; and
step H3, determining which conversion unit has insulation abnormality.

7. The method for detecting and locating insulation state according to claim 4, wherein the AC side of the AC/DC converter of each conversion unit is connected in parallel to a third switch, and the corresponding conversion unit is bypassed by turning on the third switch.

8. The method for detecting and locating insulation state according to claim 4, wherein the AC/DC converter uses a full bridge circuit, and the corresponding conversion unit is bypassed by turning on all upper switches of the AC/DC converter.

9. The method for detecting and locating insulation state according to claim 1, wherein the n conversion units comprise a first conversion unit to a n-th conversion unit, each conversion unit comprises an AC/DC converter, a DC/AC converter and a first capacitor connected in parallel to a DC side of the AC/DC converter, the AC/DC converter, the DC/AC converter and the transformer are electrically connected sequentially, AC sides of the AC/DC converters of the first conversion unit to the n-th conversion unit are connected in series sequentially, a voltage across the first capacitor is Vdc, and when voltages across the AC sides of the AC/DC converters of the n conversion units are all 0, the method for detecting and locating insulation state comprises:
step V1, connecting one conversion unit each time, wherein connecting one conversion unit refers to that an absolute value of the voltage across the AC side of the conversion unit is Vdc, starting to connect sequentially from the first conversion unit, if connecting to the i-th conversion unit, where 1≤i≤n, and insulation abnormality occurs, stopping connection, determining that the i-th conversion unit has insulation abnormality, and if connecting to the n-th conversion unit, and insulation abnormality still does not occur, performing step V2;
step V2, connecting two conversion units each time, starting to sequentially increase the serial number of the conversion unit whose serial number is smaller in the two conversion units from 1, when connecting to the k-th conversion unit whose serial number is smaller in the two conversion units, where 1≤k≤n−1, and insulation abnormality occurs, stopping connection, determining that the k-th conversion unit has insulation abnormality, and when connecting to the (n−1)th conversion unit whose serial number is smaller in the two conversion units, and insulation abnormality still does not occur, performing step Vm;
step Vm, connecting m conversion units each time, where m starts from 3, starting to sequentially increase the serial number of the conversion unit whose serial number is the smallest in the m conversion units from 1, when connecting to the j-th conversion unit whose serial number is the smallest in the m conversion units, where 1≤j≤n−m+1, and insulation abnormality occurs, stopping connection, determining that the j-th conversion unit has insulation abnormality, when connecting to the (n−m+1)th conversion unit whose serial number is the smallest in the m conversion units, and insulation abnormality still does not occur, increasing m sequentially, and when m is increased to (n−2), if insulation abnormality still does not occur, performing step Vn−1; and
step Vn−1, connecting the first conversion unit to the (n−1)th conversion unit simultaneously, if insulation abnormality occurs, determining that the (n−1)th conversion unit has insulation abnormality, and if insulation abnormality does not occur, determining that the n-th conversion unit has insulation abnormality.

10. The method for detecting and locating insulation state according to claim 1, wherein the n conversion units comprise a first conversion unit to a n-th conversion unit, each conversion unit comprises an AC/DC converter, a DC/AC converter and a first capacitor connected in parallel to a DC side of the AC/DC converter, the AC/DC converter, the DC/AC converter and the transformer are electrically connected sequentially, AC sides of the AC/DC converters of the first conversion unit to the n-th conversion unit are connected in series sequentially, a voltage across the first capacitor is Vdc, and when voltages across the AC sides of the AC/DC converters of the n conversion units are all 0, the method for detecting and locating insulation state comprises:
step P1, connecting one conversion unit each time, connecting sequentially from the first conversion unit to the n-th conversion unit, wherein connecting one conversion unit refers to that an absolute value of the voltage across the AC side of the conversion unit is equal to Vdc;
step P2, connecting two conversion units each time, and starting to sequentially increase the serial number of the conversion unit with the minimum serial number in the two conversion units from 1 to n−1;
step Pm, connecting m conversion units each time, and starting to sequentially increase the serial number of the conversion unit with the minimum serial number in the m conversion units from 1 to n−m+1, m=3, 4 . . . n−2;
step Pn−1, connecting the first conversion unit to the (n−1)th conversion unit simultaneously; and
step Pn, determining which conversion unit has insulation abnormality.

11. The method for detecting and locating insulation state according to claim 1, wherein the n conversion units comprise a first conversion unit to a n-th conversion unit, each conversion unit comprises an AC/DC converter, a DC/AC converter and a first capacitor connected in parallel to a DC side of the AC/DC converter, the AC/DC converter, the DC/AC converter and the transformer are electrically connected sequentially, AC sides of the AC/DC converters of the first conversion unit to the n-th conversion unit are connected in series sequentially, a voltage across the first capacitor is Vdc, and when voltages across the AC sides of the AC/DC converters of the n conversion units are all 0, the method for detecting and locating insulation state comprises:
step F1, selecting m conversion units to connect from the n conversion units, which totally completes Cn connecting combinations;
step F2, taking m from a set {1, 2 . . . n}, and performing the step F1 once corresponding to each value of m; and
step F3, determining which conversion unit has insulation abnormality.

12. The method for detecting and locating insulation state according to claim 1, wherein each conversion unit further comprises a DC/AC converter, an AC/DC converter, a first capacitor connected in parallel to a DC side of the DC/AC converter, and a second capacitor connected in parallel to a DC side of the AC/DC converter, the DC/AC converter, the transformer and the AC/DC converter are electrically connected sequentially, the first winding and the DC/AC converter are electrically connected, the second winding and the AC/DC converter are electrically connected, the DC sides of the DC/AC converters of the n conversion units are connected in series or in parallel, and the DC sides of the AC/DC converters of the n conversion units are connected in parallel, the method further comprising step S12 before the step S1:
connecting the first winding of each conversion unit to a positive terminal of the first capacitor of the corresponding conversion unit, and connecting the second winding of each conversion unit to a negative terminal of the second capacitor of the corresponding conversion unit.

13. The method for detecting and locating insulation state according to claim 12,
wherein when the conversion system has insulation abnormality, the first winding of the transformer in the i-th conversion unit is electrically connected to the negative terminal of the first capacitor of the corresponding conversion unit, where 1≤i≤n, and if insulation abnormality disappears, it is determined that the i-th conversion unit has insulation abnormality.

14. The method for detecting and locating insulation state according to claim 1, wherein each conversion unit further comprises a DC/AC converter, an AC/DC converter, a first capacitor connected in parallel to a DC side of the DC/AC converter, and a second capacitor connected in parallel to a DC side of the AC/DC converter, the DC/AC converter, the transformer and the AC/DC converter are electrically connected sequentially, the first winding and the DC/AC converter are electrically connected, the second winding and the AC/DC converter are electrically connected, the DC sides of the DC/AC converters of the n conversion units are connected in series or in parallel, and the DC sides of the AC/DC converters of the n conversion units are connected in parallel, the method further comprising step S13 before the step S1:
connecting the first winding of each conversion unit to a negative terminal of the first capacitor of the corresponding conversion unit, and connecting the second winding of each conversion unit to a negative terminal of the second capacitor of the corresponding conversion unit.

15. The method for detecting and locating insulation state according to claim 14, wherein the first winding of the transformer in the i-th conversion unit is electrically connected to a positive terminal of the first capacitor of the corresponding conversion unit, where 1≤i≤n, and if insulation abnormality occurs, it is determined that the i-th conversion unit has insulation abnormality.

16. The method for detecting and locating insulation state according to claim 12, wherein the DC/AC converter and the AC/DC converter use full bridge circuits, the corresponding first winding of the DC/AC converter is connected to the positive terminal of the first capacitor by turning on all upper switches of the DC/AC converter, and the corresponding second winding of the AC/DC converter is connected to the negative terminal of the second capacitor by turning on all lower switches of the AC/DC converter.

17. A device for detecting and locating insulation state of a conversion system, the conversion system comprising:
a converter module comprising n conversion units, where n≥2, each conversion unit comprising a transformer comprising a first winding and a second winding; and
a connection element connected between the first winding and the second winding of the transformer; the device for detecting and locating insulation state comprising:
a control unit connected to the converter module for changing a state of at least one switch in the conversion system, such that a voltage applied between the first winding and the second winding of the transformer in at least one of the n conversion units changes;
an insulation detecting unit nested onto the connection element and connected to the control unit for detecting a value reflecting a current flowing through the connection element before change of the state of the at least one switch and a value reflecting a current flowing through the connection element after change of the state of the at least one switch, respectively; and
a processing unit connected to the insulation detecting unit for comparing the value reflecting the current flowing through the connection element before change of the state of the at least one switch with the value reflecting the current flowing through the connection element after change of the state of the at least one switch, and determining which of the n conversion units has insulation abnormality based on comparison result.

18. The device for detecting and locating insulation state according to claim 17, wherein the conversion system further comprises a first switch connected between a power supply and an input end of the converter module, each conversion unit comprises a first capacitor, the first switch is configured to be turned on before the power supply precharges the first capacitor, and turned off till a voltage of the first capacitor is charged to a preset voltage value.

19. The device for detecting and locating insulation state according to claim 17, wherein the conversion system further comprises a second switch connected in series with the connection element, each conversion unit comprises a first capacitor, and the second switch is configured to be turned on when a voltage of the first capacitor reaches or exceeds a preset voltage value.

20. The device for detecting and locating insulation state according to claim 17, wherein the n conversion units comprise a first conversion unit to a n-th conversion unit, each conversion unit further comprises an AC/DC converter, a DC/AC converter and a first capacitor connected in parallel to a DC side of the AC/DC converter, the AC/DC converter, the DC/AC converter and the transformer are electrically connected sequentially, AC sides of the AC/DC converters of the first conversion unit to the n-th conversion unit are connected in series sequentially, a voltage across the first capacitor is Vdc, and when absolute values of voltages across the AC sides of the AC/DC converters of the n conversion units are all Vdc, if the conversion system has insulation abnormality, the device for detecting and locating insulation state performs steps of:
step R1, bypassing one conversion unit each time, wherein bypassing one conversion unit refers to that the voltage across the AC side of the conversion unit is equal to 0, starting to bypass sequentially from the first conversion unit, if bypassing to the i-th conversion unit, where 1≤i≤n, and insulation abnormality disappears, stopping bypass, determining that the i-th conversion unit has insulation abnormality, and if bypassing sequentially to the n-th conversion unit, and insulation abnormality still does not disappear, performing step R2;
step R2, bypassing two conversion units each time, starting to sequentially increase the serial number of the conversion unit whose serial number is smaller in the two conversion units from 1, when bypassing to the k-th conversion unit whose serial number is smaller in the two conversion units, where 1≤k≤n−1, and insulation abnormality disappears, stopping bypass, determining that the k-th conversion unit has insulation abnormality, and when bypassing to the conversion unit with the minimum serial number in the two conversion units which is the (n−1)th conversion unit, and insulation abnormality still does not disappear, performing step Rm;
step Rm, bypassing m conversion units each time, where m starts from 3, starting to sequentially increase the serial number of the conversion unit with whose serial number is the smallest in the m conversion units from 1, when bypassing to the j-th conversion unit whose serial number is smallest in the m conversion units, where 1≤j≤n−m+1, and insulation abnormality disappears, stopping bypass, determining that the j-th conversion unit has insulation abnormality, when bypassing to the (n−m+1)th conversion unit whose serial number is the smallest in the m conversion units, and insulation abnormality still does not disappear, increasing m, and when m is increased to (n−2), if insulation abnormality still does not disappear, performing step Rn−1; and
step Rn−1, bypassing the first conversion unit to the (n−1)th conversion unit simultaneously, if insulation abnormality disappears, determining that the (n−1)th conversion unit has insulation abnormality, and if insulation abnormality does not disappear, determining that the n-th conversion unit has insulation abnormality.

21. The device for detecting and locating insulation state according to claim 17, wherein the n conversion units comprise a first conversion unit to a n-th conversion unit, each conversion unit further comprises an AC/DC converter, a DC/AC converter and a first capacitor connected in parallel to a DC side of the AC/DC converter, the AC/DC converter, the DC/AC converter and the transformer are electrically connected sequentially, AC sides of the AC/DC converters of the first conversion unit to the n-th conversion unit are connected in series sequentially, a voltage across the first capacitor is Vdc, and when absolute values of voltages across the AC sides of the AC/DC converters of the n conversion units are all Vdc, if the conversion system has insulation abnormality, the device for detecting and locating insulation state performs steps of:
step Q1, bypassing one conversion unit each time, bypassing sequentially from the first conversion unit to the n-th conversion unit, wherein bypassing one conversion unit refers to that a voltage across the AC side of the conversion unit is equal to 0;
step Q2, bypassing two conversion units each time, and starting to sequentially increase the serial number of the conversion unit with the minimum serial number in the two conversion units from 1 to n−1;
step Qm, bypassing m conversion units each time, and starting to sequentially increase the serial number of the conversion unit with the minimum serial number in the m conversion units from 1 to n−m+1, m=3, 4 . . . n−2;
step Qn−1, bypassing the first conversion unit to the (n−1)th conversion unit simultaneously; and
step Qn, determining which conversion unit has insulation abnormality.

22. The device for detecting and locating insulation state according to claim 17, wherein the n conversion units comprise a first conversion unit to a n-th conversion unit, each conversion unit further comprises an AC/DC converter, a DC/AC converter and a first capacitor connected in parallel to a DC side of the AC/DC converter, the AC/DC converter, the DC/AC converter and the transformer are electrically connected sequentially, AC sides of the AC/DC converters of the first conversion unit to the n-th conversion unit are connected in series sequentially, a voltage across the first capacitor is Vdc, and when absolute values of voltages across the AC sides of the AC/DC converters of the n conversion units are all Vdc, if the conversion system has insulation abnormality, the device for detecting and locating insulation state performs steps of:
step H1, selecting m conversion units to bypass from the n conversion units, which totally completes Cₙ^{m} bypass combinations;
step H2, taking m from a set {1, 2 . . . n}, and performing the step H1 once corresponding to each value of m; and
step H3, determining which conversion unit has insulation abnormality.

23. The device for detecting and locating insulation state according to claim 20, wherein the AC side of the AC/DC converter of each conversion unit is connected in parallel to a third switch.

24. The device for detecting and locating insulation state according to claim 17, wherein the n conversion units comprise a first conversion unit to a n-th conversion unit, each conversion unit further comprises an AC/DC converter, a DC/AC converter and a first capacitor connected in parallel to a DC side of the AC/DC converter, the AC/DC converter, the DC/AC converter and the transformer are electrically connected sequentially, AC sides of the AC/DC converters of the first conversion unit to the n-th conversion unit are connected in series sequentially, a voltage across the first capacitor is Vdc, and when voltages across the AC sides of the AC/DC converters of the n conversion units are all 0, the device for detecting and locating insulation state performs steps of:
step V1, connecting one conversion unit each time, wherein connecting one conversion unit refers to that an absolute value of the voltage across the AC side of the conversion unit is equal to Vdc, starting to connect sequentially from the first conversion unit, if connecting to the i-th conversion unit, where 1≤i≤n, and insulation abnormality occurs, stopping connection, determining that the i-th conversion unit has insulation abnormality, and if connecting to the n-th conversion unit, and insulation abnormality still does not occur, performing step V2;
step V2, connecting two conversion units each time, starting to sequentially increase the serial number of the conversion unit whose serial number is smaller in the two conversion units from 1, when connecting to the k-th conversion unit whose serial number is smaller in the two conversion units, where 1≤k≤n−1, and insulation abnormality occurs, stopping connection, determining that the k-th conversion unit has insulation abnormality, and when connecting to the (n−1)th conversion unit whose serial number is smaller in the two conversion units, and insulation abnormality still does not occur, performing step Vm:
step Vm, connecting m conversion units each time, where m starts from 3, starting to sequentially increase the serial number of the conversion unit whose serial number is the smallest in the m conversion units from 1, when connecting to the j-th conversion unit whose serial number is the smallest in the m conversion units, where 1≤j≤n−m+1, and insulation abnormality occurs, stopping connection, determining that the j-th conversion unit has insulation abnormality, when connecting to the (n−m+1)th conversion unit whose serial number is the smallest in the m conversion units, and insulation abnormality still does not occur, increasing m sequentially, and when m is increased to (n−2), if insulation abnormality still does not occur, performing step Vn−1; and
step Vn−1, connecting the first conversion unit to the (n−1)th conversion unit simultaneously, if insulation abnormality occurs, determining that the (n−1)th conversion unit has insulation abnormality, and if insulation abnormality does not occur, determining that the n-th conversion unit has insulation abnormality.

25. The device for detecting and locating insulation state according to claim 17, wherein the n conversion units comprise a first conversion unit to a n-th conversion unit, each conversion unit further comprises an AC/DC converter, a DC/AC converter and a first capacitor connected in parallel to a DC side of the AC/DC converter, the AC/DC converter, the DC/AC converter and the transformer are electrically connected sequentially, AC sides of the AC/DC converters of the first conversion unit to the n-th conversion unit are connected in series sequentially, a voltage across the first capacitor is Vdc, and when voltages across the AC sides of the AC/DC converters of the n conversion units are all 0, the device for detecting and locating insulation state performs steps of:
step P1, connecting one conversion unit each time, connecting sequentially from the first conversion unit to the n-th conversion unit, wherein connecting one conversion unit refers to that an absolute value of the voltage across the AC side of the conversion unit is equal to Vdc;
step P2, connecting two conversion units each time, and starting to sequentially increase the serial number of the conversion unit with the minimum serial number in the two conversion units from 1 to n−1;
step Pm, connecting m conversion units each time, and starting to sequentially increase the serial number of the conversion unit with the minimum serial number in the m conversion units from 1 to n−m+1, m=3, 4 . . . n−2;
step Pn−1, connecting the first conversion unit to the (n−1)th conversion unit simultaneously; and
step Pn, determining which conversion unit has insulation abnormality.

26. The device for detecting and locating insulation state according to claim 17, wherein the n conversion units comprise a first conversion unit to a n-th conversion unit, each conversion unit further comprises an AC/DC converter, a DC/AC converter and a first capacitor connected in parallel to a DC side of the AC/DC converter, the AC/DC converter, the DC/AC converter and the transformer are electrically connected sequentially, AC sides of the AC/DC converters of the first conversion unit to the n-th conversion unit are connected in series sequentially, a voltage across the first capacitor is Vdc, and when voltages across the AC sides of the AC/DC converters of the n conversion units are all 0, the device for detecting and locating insulation state performs steps of:
step F1, selecting m conversion units to connect from the n conversion units, which totally completes Cn connecting combinations;
step F2, taking m from a set {1, 2 . . . n}, and performing the step F1 once corresponding to each value of m; and
step F3, determining which conversion unit has insulation abnormality.

27. The device for detecting and locating insulation state according to claim 17, wherein each conversion unit further comprises a DC/AC converter, an AC/DC converter, a first capacitor connected in parallel to a DC side of the DC/AC converter, and a second capacitor connected in parallel to a DC side of the AC/DC converter, the DC/AC converter, the transformer and the AC/DC converter are electrically connected sequentially, the first winding and the DC/AC converter are electrically connected, the second winding and the AC/DC converter are electrically connected, the DC sides of the DC/AC converters of the n conversion units are connected in series or in parallel, and the DC sides of the AC/DC converters of the n conversion units are connected in parallel, the control unit allows that the first winding of each conversion unit is connected to a positive terminal of the first capacitor of the corresponding conversion unit, and the second winding of each conversion unit is connected to a negative terminal of the second capacitor of the corresponding conversion unit.

28. The device for detecting and locating insulation state according to claim 27, wherein when the conversion system has insulation abnormality, the first winding of the transformer in the i-th conversion unit is electrically connected to the negative terminal of the first capacitor of the corresponding conversion unit, where 1≤i≤n, and if insulation abnormality disappears, it is determined that the i-th conversion unit has insulation abnormality.

29. The device for detecting and locating insulation state according to claim 17, wherein each conversion unit further comprises a DC/AC converter, an AC/DC converter, a first capacitor connected in parallel to a DC side of the DC/AC converter, and a second capacitor connected in parallel to a DC side of the AC/DC converter, the DC/AC converter, the transformer and the AC/DC converter are electrically connected sequentially, the first winding and the DC/AC converter are electrically connected, the second winding and the AC/DC converter are electrically connected, the DC sides of the DC/AC converters of the n conversion units are connected in series or in parallel, the DC sides of the AC/DC converters of the n conversion units are connected in parallel, and the control unit allows that the first winding of each conversion unit is connected to a negative terminal of the first capacitor of the corresponding conversion unit, and the second winding of each conversion unit is connected to a negative terminal of the second capacitor of the corresponding conversion unit.

30. The device for detecting and locating insulation state according to claim 29, wherein the first winding of the transformer in the i-th conversion unit is electrically connected to a positive terminal of the first capacitor of the corresponding conversion unit, where 1≤i≤n, and if insulation abnormality occurs, it is determined that the i-th conversion unit has insulation abnormality.
